(19) United States
(12) Patent Application Publication
(10) Pub. No.: US 2019/0343025 A1
(43) Pub. Date: Nov. 7, 2019

(54) DATA CENTER LIQUID CONDUCTION COOLING APPARATUS AND METHOD

(71) Applicant: Nautilus Data Technologies, Inc., Pleasanton, CA (US)

(72) Inventors: Arnold C. Magcale, Danville, CA (US); Byron Putnam Taylor, San Jose, CA (US); Chase Abercrombie Ott, San Rafael, CA (US); James Connaughton, Palo Alto, CA (US)

(21) Appl. No.: 15/972,066

(22) Filed: May 4, 2018

(51) Int. Cl. H05K 7/20

(52) U.S. Cl. CPC H05K 7/20763; H05K 7/20281; H05K 7/20272; H05K 7/20263

(57) ABSTRACT

Embodiments disclosed include a heat exchange apparatus comprising an equipment-side coolant circuit configured for fluid communication with a first coolant compartment via a first coolant in-flow and out-flow valve. The embodiment further comprises a second coolant compartment operatively coupled to the first coolant compartment and comprising a second coolant in-flow and out-flow valve in fluid communication with a coolant supply source. The first coolant compartment is calibrated to receive hot coolant via the first coolant in-flow valve from a heat transfer element comprised in the equipment side coolant circuit line coupled to a heat generating source and in fluid communication with the first coolant in-flow valve, and the first coolant out-flow valve is calibrated to return the coolant to the heat transfer element comprised in the equipment side coolant circuit line. The second coolant compartment is calibrated to receive cold coolant from the coolant supply source via the second coolant in-flow valve and to return the received cold coolant to the coolant supply source via the second coolant out-flow valve in an open-loop coolant circuit line.

### CROSS REFERENCE TO RELATED APPLICATIONS

This application bears reference to application Ser. No. 14/280,040 filed May 16, 2014, having a priority date of Jan. 8, 2014, and entitled “A WATERBASED CLOSED-LOOP COOLING SYSTEM” the contents of which are incorporated by reference in their entirety.

### FIELD

The present invention relates to heat transfer systems and methods, and more particularly, to liquid cooled conduction cooling apparatuses, liquid-cooled elegy electronics racks and methods of fabrication thereof for removing heat generated by one or more electronic systems. Still more particularly, the present invention relates to cooling apparatuses and cooled electronics racks, cooled by modular, stacked heat exchangers comprising complimentary open and closed loop liquid-flow compartments.

### BACKGROUND OF THE INVENTION

A data center is a facility used to house computer systems and associated components. The computer systems, associated components housed in data centers and the environmental control cooling systems therein, consume significant amounts of energy. With the modern data center requiring several megawatts (MW) of power to support and cool the computer systems and associated components therein, resource utilization efficiency has become critical to evaluating data center performance.

To support the power consumption of the computer systems, associated components housed in the data centers and environmental control cooling systems, data centers consume a significant amount of water annually. Data center cooling system efficiency is critical to reduce the number of litres of water used per kilowatt hour (kWh) of energy consumed by the computer systems and associated components housed in the data center.

Prior art methods and systems have attempted to develop multi metric views to provide a broader understanding of data center performance. These multi metric views often take into account a single aspect of data center performance, Power Usage Effectiveness (PUE), a measure of how efficiently a data center uses energy. However, there still remains a need for a more nuanced and multi-dimensional metric that addresses the critical aspects of data center performance. In order to establish a more complete view of data center performance, there exists a requirement to assess key aspects of data center performance such as data center efficiency, data center availability and data center sustainability. There remains an additional need for a multi-dimensional metric that is easily scalable and that can accommodate additional new metrics in the future, as they are defined. Embodiments disclosed address precisely such a need.

With exponential increases in compute power density, data center electronics produce more and more heat. Failure to remove heat effectively results in increased device temperatures, potentially leading to thermal runaway conditions. The need for faster and more densely packed circuits has had a direct impact on the importance of thermal management. First, power dissipation, and therefore heat production, increases as device operating frequencies increase. Second, increased operating frequencies may be possible at lower device junction temperatures. Further, as more and more devices are packed onto a single chip, heat flux (Watts/cm²) increases, resulting in the need to remove heat expeditiously from a given size chip or module. These trends have combined to create applications where it is no longer desirable to remove heat from modern devices solely by traditional air cooling methods, such as by using air cooled heat sinks with heat pipes or vapour chambers. Such air cooling techniques are inherently limited in their ability to extract heat from an electronic device with high power density.

The need to cool current and future high heat load, high heat flux electronic devices and systems therefore mandates the development of aggressive thermal management techniques using liquid cooling. Embodiments disclosed address precisely such a need.

Multiple electronic equipment units are often housed in high-density assemblies, such as server racks, in which modular electronic equipment units (e.g., servers) are mounted on an upright frame or rack in a vertically spaced, stacked arrangement. Large numbers of such server racks, for example, may in turn be housed together in a high-density electronic equipment facility or data center.

Electronic equipment generates heat, typically requiring cooling to prevent overheating. The importance of heat management is amplified when electronic equipment is located in concentrated density, for example, server racks and data centers. Cooling of rack-mounted server components can be achieved by direct liquid cooling, which sometimes entails circulating a liquid coolant along sealed conduits that pass through the servercasings in heat exchange relationship with server components. A complication of direct liquid cooling is that it necessarily brings liquid coolant into close proximity with liquid-intolerant electronic components and is thus perceived as exposing the server rack and/or data center to substantial leakage failure risks.

### SUMMARY

Embodiments disclosed include a heat exchange apparatus comprising an equipment-side coolant circuit line configured for fluid communication with a first coolant compartment via a corresponding first coolant in-flow and out-flow valve. According to an embodiment the heat exchange apparatus further comprises a second coolant compartment operatively coupled to the first coolant compartment and comprising a corresponding second coolant in-flow and out-flow valve in fluid communication with a coolant supply source. In an embodiment, the first coolant compartment is calibrated to receive coolant via the first coolant in-flow valve in a closed loop comprised in the equipment side coolant circuit line, wherein the first coolant compartment is in thermal communication with a heat generating source and the second coolant compartment, and the first coolant compartment out-flow valve is calibrated to return cooled coolant to the heat generating source via the closed loop coolant circuit line. Preferably, the second coolant compartment is calibrated to receive cold coolant from the coolant supply source via the second coolant in-flow valve and to return warmed coolant to the coolant supply source via the second coolant out-flow valve.

Embodiments disclosed include, in a heat exchange apparatus, a method comprising initiating fluid communication between an equipment-side coolant circuit line with a first coolant compartment via a corresponding first coolant in-flow and out-flow valve. According to an embodiment the method further includes initiating fluid communication between a coolant supply source and a second coolant compartment operatively coupled to the first coolant compartment via a corresponding second coolant in-flow and out-flow valve. Preferably, the first coolant compartment receives hot coolant via the first coolant in-flow valve from a heat transfer element comprised in the equipment side coolant circuit line coupled to a heat generating source and in fluid communication with the first coolant in-flow valve, and the first coolant out-flow vale returns the coolant to the heat transfer element comprised in the equipment side coolant circuit line. An embodiment includes an open loop coolant circuit line, wherein the second coolant compartment receives cold coolant from the coolant supply source via the second coolant in-flow valve and returns warmed coolant to the coolant supply source via the second coolant out-flow valve.

### BRIEF DESCRIPTION OF THE DRAWINGS

FIG. 1 illustrates a cooling apparatus in an ABAB orientation according to an embodiment.

FIG. 2 illustrates a cooling apparatus in a BAABAA orientation according to an alternate embodiment.

FIG. 3 illustrates a cooling apparatus in a BCBBCB orientation according to an embodiment.

### DETAILED DESCRIPTION

The following is a detailed description of embodiments of the invention depicted in the accompanying drawings. The embodiments are introduced in such detail as to clearly communicate the invention. However, the embodiment(s) presented herein are merely illustrative and are not intended to limit the anticipated variations of such embodiments; on the contrary, the intention is to cover all modifications, equivalents, and alternatives falling within the spirit and scope of the appended claims. The detailed descriptions below are designed to make such embodiments obvious to those of ordinary skill in the art.

As stated above, the traditional way of monitoring data center infrastructure, collecting data from infrastructure systems, and managing the systems to allow maximizing the operational efficiency is now struggling to cope with new challenges brought by the growing complexity of data centers. Traditional cooling systems and methods are hopelessly inadequate in light of current scale and increased compute density. Embodiments disclosed include systems and methods that address these challenges effectively and efficiently.

Embodiments disclosed include a heat exchange apparatus comprising an equipment-side coolant circuit line configured for fluid communication with a first coolant compartment via a corresponding first coolant in-flow and out-flow valve. The embodiment further comprises a second coolant compartment operatively coupled to the first coolant compartment and comprising a corresponding second coolant in-flow and out-flow valve in fluid communication with a coolant supply source. Preferably, the first coolant compartment is calibrated to receive hot coolant via the first coolant in-flow valve from a heat transfer element comprised in the equipment side coolant circuit line coupled to a heat generating source and in fluid communication with the first coolant in-flow valve, and the first coolant out-flow valve is calibrated to return the cooled coolant to the heat transfer element comprised in the equipment side coolant circuit line. Additionally, the second coolant compartment is calibrated to receive cold coolant from the coolant supply source via the second coolant in-flow valve and to return warmed coolant to the coolant supply source via the second coolant out-flow valve in an open loop coolant circuit line.

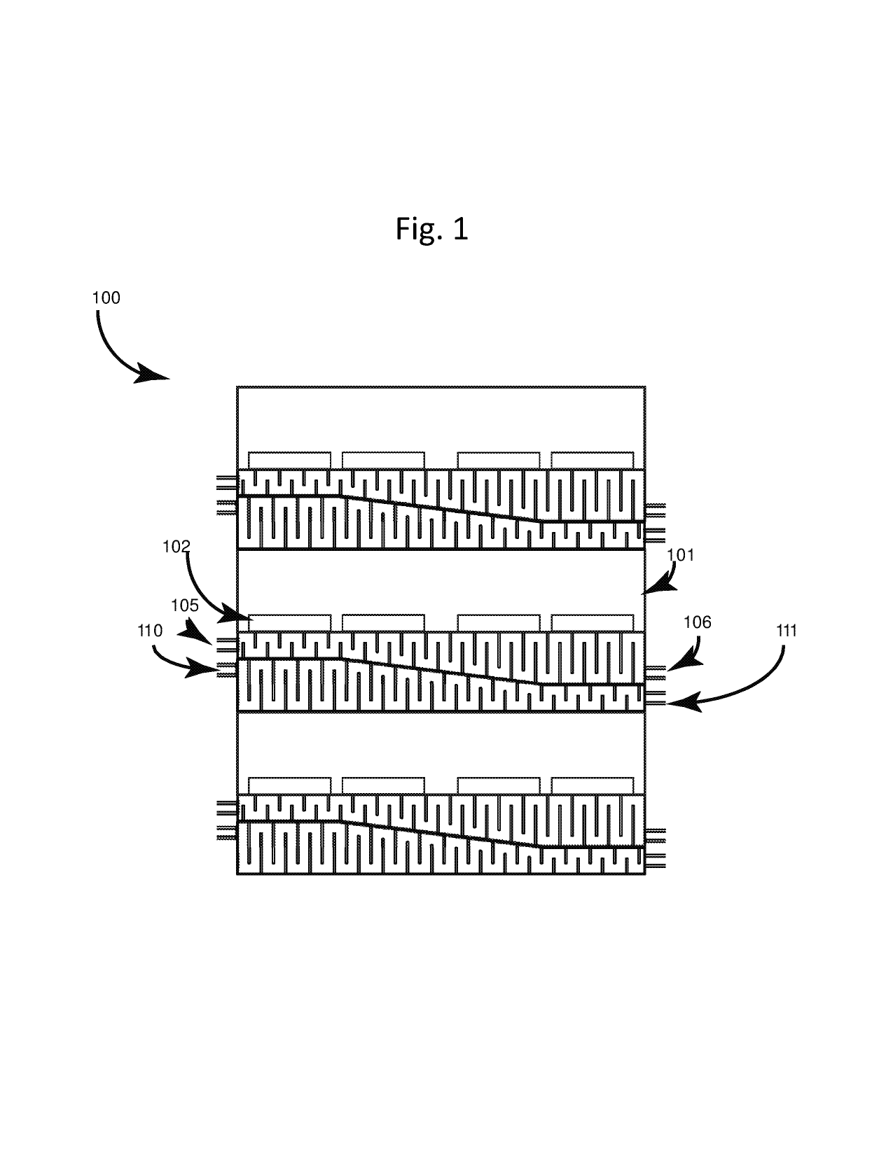

FIG. 1 illustrates a cooling apparatus in an ABAB orientation according to an embodiment. FIG. 1 illustrates a drawing 100 of an ABAB orientation, wherein heat exchange apparatus 101 comprising equipment side coolant circuit line 103 configured for fluid communication with first coolant compartment 104 via corresponding first coolant in-flow valve 110 and out-flow valve 111. Second coolant compartment 107 operatively coupled to first coolant compartment 104 and corresponding second coolant in-flow valve 106 and out-flow valve 105 in fluid communication with a coolant supply source (not shown). First coolant compartment 104 receives hot coolant via first coolant in-flow valve 110 from heat transfer element (not shown) comprised in the equipment side coolant circuit line coupled to heat generating source 102 in fluid communication with first coolant in-flow valve 110, and first coolant out-flow valve returns the coolant to heat transfer element. Second coolant compartment 107 receives cold coolant from the coolant supply source (not shown) via second coolant in-flow valve 106 and returns the received cold coolant to the coolant supply source via second coolant out-flow valve 105. The electronics rack includes server 101 comprising Central Processing Unit (heat generating source) 102 coupled to heat exchange element (not shown) in fluid communication with heat exchange apparatus 101 via closed loop inflow valve 110 and closed loop outflow valve 111. Heat exchange apparatus 101 is further shown to comprise open loop inflow valve 106 and open loop outflow valve 105.

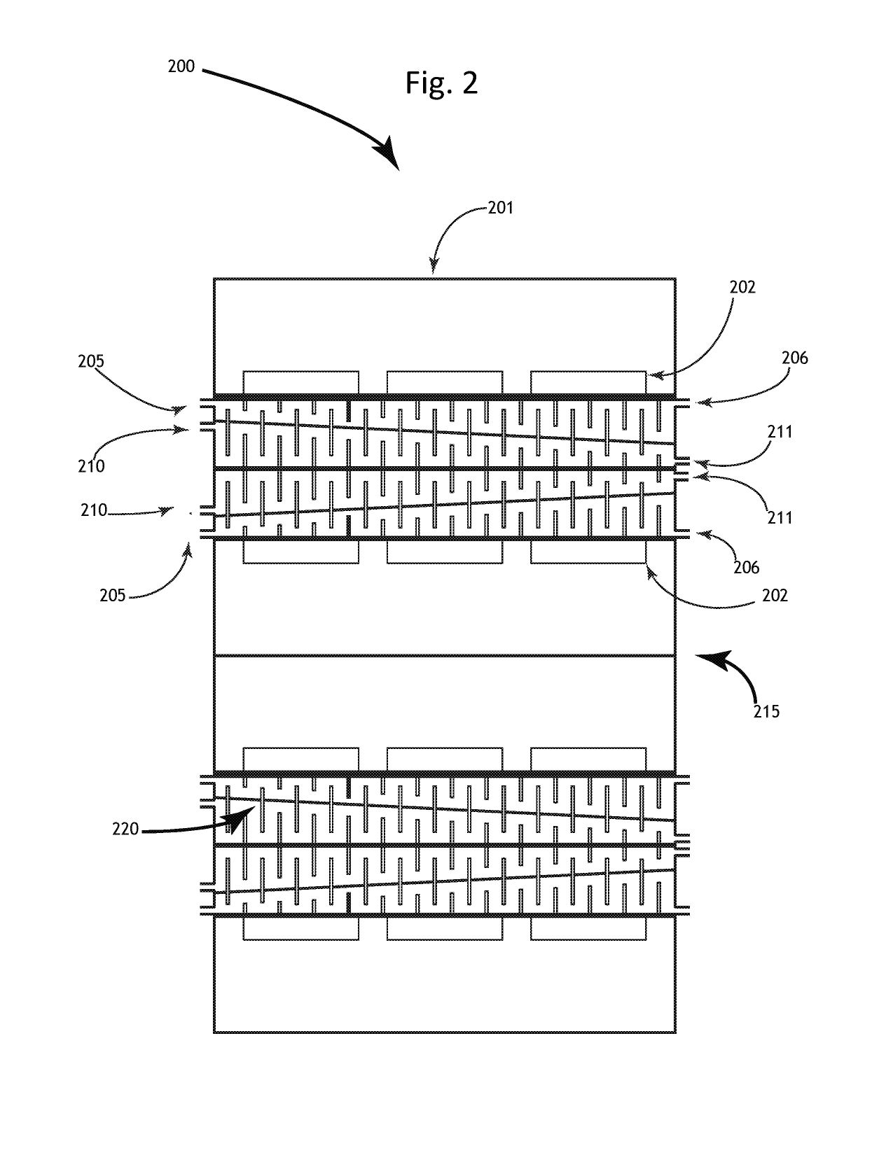

FIG. 2 illustrates a cooling apparatus in a BAABAA orientation according to an alternate embodiment. FIG. 2 illustrates in drawing 200, a BAABAA orientation, wherein servers 201 are inverted such that two servers are sandwiched between two heat exchange apparatuses. According to an embodiment the heat exchange apparatus comprises a single piece fin body 205 between the cold and hot side of the heat exchanger.

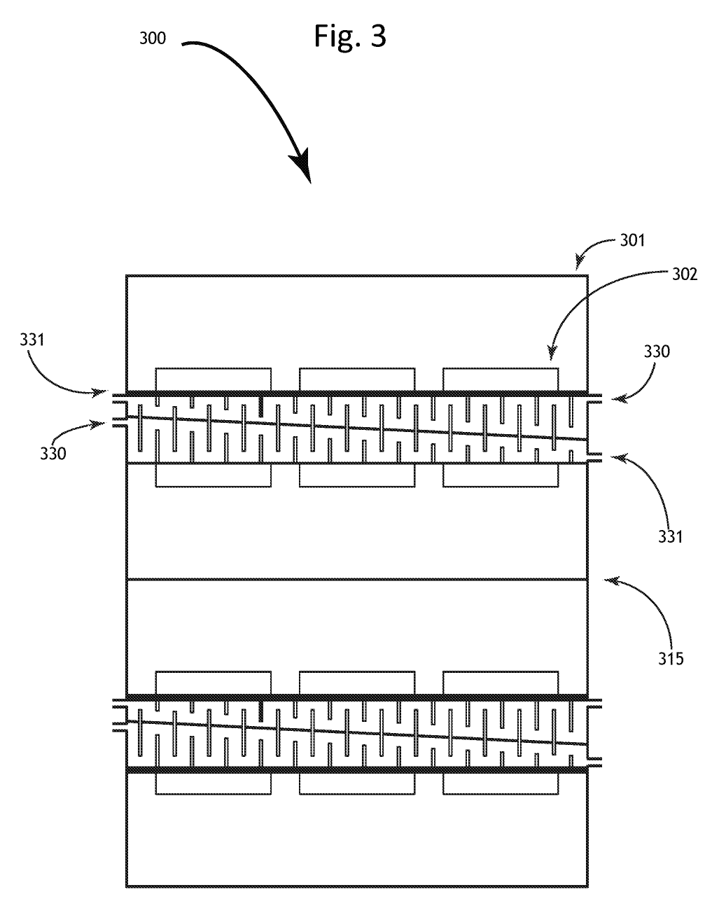

FIG. 3 illustrates a cooling apparatus in a BCBBCB orientation according to an embodiment. FIG. 3 illustrates in drawing 300 a BCBBCB orientation, where C is a heat exchanger with two cold sides comprising heat exchanger in-flow valve 301 and heat exchanger out-flow valve 302.

According to an embodiment of the heat exchange apparatus, the equipment-side coolant circuit line is a closed loop coolant circuit. Alternatively, an open loop coolant circuit line can be implemented, as would be apparent to a person having ordinary skill in the art. According to a preferred embodiment of the heat exchange apparatus, the second coolant in-flow and out-flow valves in fluid communication with the coolant supply source are comprised in an open loop coolant circuit line. Further, the first coolant in-flow and out-flow direction is opposite to the second coolant in-flow and out-flow direction respectively.

Embodiments disclosed include a heat exchange apparatus wherein the heat exchange apparatus is a rack mounted module operatively coupled to a corresponding rack mounted electronic server module wherein the first coolant in-flow and out-flow compartment is comprised in a rack mounted closed loop coolant distribution unit and the second coolant in-flow and out-flow compartment is comprised in an open loop coolant distribution unit. Alternatively, the rack mounted heat exchange apparatus is stacked between two heat generating sides of rack mounted electronic server modules, and cold water from a coolant source is pumped through both the first and second coolant compartments through the first and second coolant inflow and out-flow valves in each of the first and second compartments, respectively in a Direct Contact Liquid Cooling (DCLC) configuration.

According to an embodiment the heat exchange apparatus further comprises a control system comprising a sensor arrangement configured to measure at least one of a volume of liquid coolant in each of the coolant compartments, and a rate of change of liquid coolant volume in each of the compartments, wherein measurements measured by the sensor arrangement are monitored by the control system to detect faults. And based on detected faults the control system is configured to generate an alarm signal responsive to a rate of change in the volume of liquid coolant in a coolant reservoir being above a predefined threshold value.

According to an embodiment and based on the detected faults derived from the change of liquid coolant volume, the control system causes a negative pressure to be created in the equipment-side coolant circuit line, and in the first and second coolant in-flow and out-flow compartments, to eliminate any spillage of liquid coolant. Preferably, the first coolant compartment circulates water in a closed loop and the second coolant compartment circulates water from a natural proximal source. However, other fluids or combination of fluids may be used. Further, variations and modifications are possible as would be apparent to a person having ordinary skill in the art.

Embodiments disclosed include, in a heat exchange apparatus, a method comprising initiating fluid communication between an equipment-side coolant circuit line with a first coolant compartment via a corresponding first coolant in-flow and out-flow valve. According to an embodiment the method further includes initiating fluid communication between a coolant supply source and a second coolant compartment operatively coupled to the first coolant compartment via a corresponding second coolant in-flow and out-flow valve. Preferably, the first coolant compartment receives hot coolant via the first coolant in-flow valve from a heat transfer element comprised in the equipment side coolant circuit line coupled to a heat generating source and in fluid communication with the first coolant in-flow valve, and the first coolant out-flow vale returns the coolant to the heat transfer element comprised in the equipment side coolant circuit line. An embodiment includes an open loop coolant circuit line, wherein the second coolant compartment receives cold coolant from the coolant supply source via the second coolant in-flow valve and returns the received cold coolant, now warmed, to the coolant supply source via the second coolant out-flow valve.

According to an embodiment of the method, initiating the fluid communication between the equipment-side coolant circuit line with the first coolant compartment comprises initiating a closed loop circuit fluid communication. Alternatively, an open loop circuit line may also be implemented. Preferably, the initiating the fluid communication between the coolant supply source and the second coolant compartment comprises initiating an open loop circuit line fluid communication. Alternatively, a closed loop circuit line may also be implemented. In one embodiment, the fluid communication between the equipment-side coolant circuit line and the first coolant compartment is in an opposite direction to the fluid communication between the coolant supply source and the second coolant compartment.

An embodiment of the method comprises operatively coupling the heat exchanger to a rack mounted electronic server module such that the first coolant compartment is comprised in a rack mounted closed loop coolant distribution unit and the second coolant compartment operatively coupled to the first coolant compartment is comprised in an open loop coolant distribution unit.

Embodiments of the disclosed method include in a control system, measuring at least one of a volume of liquid coolant in each of the coolant compartments, and a rate of change of liquid coolant volume in each of the compartments, wherein measurements measured by the sensor arrangement are monitored by the control system to detect faults. Preferably, and based on detected faults, the method includes generating an alarm signal responsive to a rate of change in the volume of liquid coolant in a coolant reservoir being above a predefined threshold value.

Preferably, and based on the detected faults derived from the change of liquid coolant volume, the method includes creating a negative pressure in the equipment-side coolant circuit, and the first and second coolant compartments to eliminate any spillage of liquid coolant. The first coolant compartment contains at least one of a fluid and water. Preferably, water from a naturally occurring proximal source is pumped through the second coolant compartment.

Embodiments disclosed include a cooling apparatus for facilitating cooling of an electronic system, the cooling apparatus comprising a liquid-cooled cooling structure comprising a first heat transfer element configured to stack beneath or above the electronic system, the liquid-cooled cooling structure comprising a thermally conductive material and comprising at least one coolant-carrying channel extending there through. According to an embodiment, a second heat transfer element coupled to one or more corresponding heat-generating components of the electronic system, is configured to physically contact the liquid-cooled cooling structure, wherein each heat transfer element physically engages the liquid-cooled cooling structure, and wherein each heat transfer element provides a thermal transport path from the one or more heat-generating components of the electronic system to the liquid-cooled cooling structure stacked beneath or above the electronic system. In a preferred embodiment, a third heat transfer element is operatively coupled to the second heat transfer element, comprising a thermally conductive material and at least one coolant carrying channel extending there through.

Embodiments disclosed include cooling apparatuses and systems for facilitating cooling of an electronic system, the cooling apparatus comprising a liquid-cooled cooling structure comprising a first heat transfer element configured to mount to a housing within which the electronic system is contained, the liquid-cooled cooling structure comprising a thermally conductive material and comprising at least one coolant-carrying channel extending there through. According to an embodiment the cooling apparatus may include a second single or plurality of heat transfer elements coupled to one or more corresponding heat-generating components of the electronic system, and configured to physically contact the liquid-cooled cooling structure when the liquid-cooled cooling structure is mounted to the housing, wherein each heat transfer element physically engages the liquid-cooled cooling structure, and wherein each heat transfer element provides a thermal transport path from the one or more heat-generating components of the electronic system to the liquid-cooled cooling structure mounted to the housing. Further the embodiment must include a third heat transfer element operatively coupled to the first heat transfer element mounted to the housing, comprising a thermally conductive material and at least one coolant carrying channel extending there through. According to an embodiment, the coolant carrying channel comprised in the cooling apparatus further comprises a single or plurality of configurable internal valves or gates operable to regulate the flow of the liquid according to a pre-defined temperature parameter. The valves or gates are mechanically, electronically or electro-mechanically controlled either by Data Center Infrastructure Management (DCIM) software, or autonomously. These dynamic flow control valves or gates to control temperature cooling enables highly targeted, specific cooling at the subsystem level.

According to an embodiment of the cooling apparatus the heat transfer element comprises a heat transfer member configured to couple to the one or more heat-generating components of the electronic system and a thermal interface plate coupled to one end of the heat transfer member, the thermal transport path passing through the heat transfer member and the thermal interface plate.

In one embodiment of the cooling apparatus, the thermal interface plate is connected at a first end thereof to the heat transfer member and is configured to physically contact at a second end thereof to the liquid-cooled cooling structure when the liquid-cooled cooling structure is mounted to the housing, the heat transfer element is coupled to the one or more heat-generating components of the electronic system.

According to an embodiment of the cooling apparatus, at least one of the heat transfer member and the thermal interface plate comprises a heat pipe defining a portion of the thermal transport path and facilitating transport of heat generated by the one or more heat-generating components of the electronic system to the liquid-cooled cooling structure.

In a preferred embodiment, the liquid-cooled cooling structure is configured to cool multiple electronic systems via multiple respective heat transfer elements configured to couple thereto.

In an alternate embodiment of the cooling apparatus, the liquid-cooled cooling structure comprises multiple coolant-carrying channels extending there through, wherein the liquid-cooled cooling structure further comprises a coolant inlet plenum and a coolant outlet plenum in fluid communication with the multiple coolant-carrying channels. Preferably, the liquid-cooled cooling structure is a monolithic structure comprising the first heat transfer element configured to attach to the housing. The housing is an electronics rack comprising multiple electronic systems.

In one embodiment, an electronic subsystem comprises multiple heat-generating components to be cooled, and the second single or plurality of heat transfer elements are thermally interfaced to at least some heat-generating components of the multiple heat-generating components to be cooled and are further configured to physically contact the liquid-cooled cooling structure when the liquid-cooled cooling structure is mounted to the housing.

Embodiments disclosed include, in an electronics rack, a liquid-cooled cooling apparatus comprising a cooling structure comprising a first heat transfer element mounted to the electronics rack, and in operative communication with a thermally conductive material comprising at least one coolant-carrying channel extending there through in a closed loop. The liquid cooling apparatus comprises a second heat transfer element coupled to the first heat transfer element and in operative communication with a thermally conductive material comprising at least one coolant-carrying channel extending there through in at least one of an open loop and a closed loop. According to an additional and alternate embodiment, the liquid cooling apparatus comprises a plurality of heat transfer elements, each heat transfer element being coupled to one or more heat-generating components of a respective electronic system of a plurality of electronic systems, and configured to physically contact the liquid-cooled cooling structure, wherein each heat transfer element physically engages the liquid-cooled cooling structure external the housing, and wherein each heat transfer element provides a thermal transport path from the one or more heat-generating components of the respective electronic system coupled thereto to the liquid-cooled cooling structure mounted to the housing.

According to an embodiment of the liquid-cooled electronics rack, the liquid-cooled cooling structure comprises at least one coolant-carrying channel extending there through, and wherein the liquid-cooled cooling structure further comprises a coolant inlet plenum and a coolant outlet plenum in fluid communication with the coolant-carrying channels, wherein the coolant inlet plenum and the coolant outlet plenum are plenums mounted to the electronics rack.

According to an embodiment of the liquid-cooled electronics rack, each heat transfer element comprises a heat transfer member coupled to the one or more heat-generating components of the respective electronic system and a thermal interface plate extending from the one end of the heat transfer member, wherein the respective thermal transport path passes through the heat transfer member and the thermal interface plate.

According to an embodiment of the liquid-cooled electronics rack, at least one of the heat transfer member and the thermal interface plate of at least one heat transfer element comprises a heat pipe defining a portion of the thermal transport path thereof and facilitating transport of heat generated by the one or more heat-generating components of the respective electronic system to the liquid-cooled cooling structure.

According to an embodiment, the heat exchange apparatus, and particularly the coolant compartments, are built entirely or substantially of open-celled metallic foams. Open-celled metallic foams, or stochastic foams, have heat transfer applications due to their large surface areas, low boundary layers, and high heat transfer coefficients offering low-weight, compact heat exchange mechanisms. Stochastic foams currently are used in defence, aerospace, and high-performance electronics applications.

A stochastic foam has a random distribution of cells compared to a <structured matrix formation>. Open celled foam is made up of a set of pores, empty volume between nodes, the intersections of struts of metal. A foam is reticulated when it is extremely open-celled and only consists of a strut lattice structure.

Metallic foams can be manufactured through additive processes or by filling a mould of the negative space and removing the mould through later steps. Stochastic foam has greater heat exchange capability and can be arranged in fins or other orientations for greater heat transfer effectiveness than solid-bodied metal fins. Reticulated stochastic foams allow for fluid to pass through the open cells and exchange heat with the metallic foam struts. Due to the low diameter of these struts, fluid can flow over them and produce very little boundary layer before interacting with another strut in the structure. This allows for the fluid to flow over the foam struts at a fairly high velocity at all surfaces of heat transfer allowing for a greater transfer of heat. The compact form of this foam allows for greater heat transfer to occur within a given volume than traditional fins.

Preferably, in the liquid-cooled electronics rack the heat exchange apparatus and method is configured to cool multiple electronic systems via multiple, respective heat transfer elements coupled thereto.

Embodiments disclosed include systems and methods for cooling data centers that contribute to optimizing data center performance and sustainability through efficient cooling and drastically reduced power consumption. Embodiments disclosed address the long-standing need to cool current and future high heat load, high heat flux electronic devices and systems through improved management techniques using liquid cooling. Embodiments disclosed facilitate water conservation and drastic reduction in water consumption for cooling data centers.

Embodiments disclosed enable drastic reduction in power consumption through smart management of cooling power and leveraging of environmental conditions to optimize cooling power consumption. Systems and methods disclosed enable huge savings in data center power consumption. Predictive analytics software control enables real-time computing power consumption estimation and thereby optimization of computing and cooling power consumption.

Embodiments disclosed include systems and methods that leverage multi-metric views that provide real-time actionable intelligence on data center performance and cooling performance. These multi-metric views attempt to take into account aspects of performance by bringing together the Power Usage Effectives (PUE) ratio, IT Thermal Conformance and IT Thermal Resilience thereby enabling real-time optimization through correlation of computing, infrastructure and cooling performance. Embodiments disclosed further enable nuanced and multi-dimensional metric that addresses the most critical aspects of a data center's cooling performance. In order to establish a more complete view of facility cooling, the requirement to calculate cooling effectiveness and the data centre's future thermal state is also critical. Embodiments disclosed enable easily scalable multi-dimensional metrics that can accommodate additional new metrics in the future, as they are defined.

Embodiments disclosed include improved, superior thermal conduction apparatuses and methods for facilitating cooling of a rack based electronic system. According to a preferred embodiment, the thermal conduction apparatus is stacked between rack mounted electronic systems. Preferably, circulation liquid coolant includes incorporating negative pressure to negate any spills during leakage. According to an embodiment, the liquid-cooling apparatus incorporates secondary closed loop for direct cooling. In an additional embodiment, heat exchangers comprising horizontal fins where the heated fluid from the server's pass-through which interlaces with opposing horizontal fins where the cold water passes through and this is where the heat conduction occurs. Preferably, there are no “removable components” each rack will have its own apparatus. According to one embodiment, each electronic system on the rack has its own heat exchange apparatus. According to another embodiment of the apparatus, there is no requirement for any air flow.

Since various possible embodiments might be made of the above invention, and since various changes might be made in the embodiments above set forth, it is to be understood that all matter herein described or shown in the accompanying drawings is to be interpreted as illustrative and not to be considered in a limiting sense. Thus, it will be understood by those skilled in the art of systems and methods that facilitate cooling of electronic systems, and more specifically automated cooling infrastructure especially pertaining to data centers, that although the preferred and alternate embodiments have been shown and described in accordance with the Patent Statutes, the invention is not limited thereto or thereby.

The figures illustrate the architecture, functionality, and operation of possible implementations of systems, methods and computer program products according to various embodiments of the present invention. It should also be noted that, in some alternative implementations, the functions noted/illustrated may occur out of the order noted in the figures. For example, two blocks shown in succession may, in fact, be executed concurrently, or the blocks may sometimes be executed in the reverse order, depending upon the functionality involved.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

In general, the routines executed to implement the embodiments of the invention, may be part of an operating system or a specific application, component, program, module, object, or sequence of instructions. The computer program of the present invention typically is comprised of a multitude of instructions that will be translated by the native computer into a machine-accessible format and hence executable instructions. Also, programs are comprised of variables and data structures that either reside locally to the program or are found in memory or on storage devices. In addition, various programs described hereinafter may be identified based upon the application for which they are implemented in a specific embodiment of the invention. However, it should be appreciated that any particular program nomenclature that follows is used merely for convenience, and thus the invention should not be limited to use solely in any specific application identified and/or implied by such nomenclature.

The present invention and some of its advantages have been described in detail for some embodiments. It should be understood that although the system and process is described with reference to liquid-cooled conduction cooling structures in data centers, the system and method is highly reconfigurable, and may be used in other contexts as well. It should also be understood that various changes, substitutions and alterations can be made herein without departing from the spirit and scope of the invention as defined by the appended claims. An embodiment of the invention may achieve multiple objectives, but not every embodiment falling within the scope of the attached claims will achieve every objective. Moreover, the scope of the present application is not intended to be limited to the particular embodiments of the process, machine, manufacture, composition of matter, means, methods and steps described in the specification. A person having ordinary skill in the art will readily appreciate from the disclosure of the present invention that processes, machines, manufacture, compositions of matter, means, methods, or steps, presently existing or later to be developed are equivalent to, and fall within the scope of, what is claimed. Accordingly, the appended claims are intended to include within their scope such processes, machines, manufacture, compositions of matter, means, methods, or steps.

We claim:

1. A heat exchange apparatus comprising:
an equipment-side coolant circuit configured for fluid communication with the heat exchange apparatus;
a first coolant in flow and out flow compartment comprising a corresponding first coolant in-flow and out-flow valve in fluid communication with the equipment side coolant circuit;
a second coolant in-flow and out-flow compartment operatively coupled to the first coolant in-flow and out-flow compartment and comprising a corresponding second coolant in-flow and out-flow valve in fluid communication with a coolant supply source;
wherein the first coolant in-flow compartment is calibrated to receive hot coolant via the first coolant in-flow valve from a heat transfer element comprised in the equipment side coolant circuit coupled to a heat generating source and in fluid communication with the first coolant in-flow valve, and the first coolant out-flow side is calibrated to return the coolant to the heat transfer element comprised in the equipment side coolant circuit; and
wherein the second coolant in-flow compartment is calibrated to receive cold coolant from the coolant supply source via the second coolant in-flow valve and to return the received cold coolant to the coolant supply source via the second coolant out-flow valve.

2. The heat exchange apparatus of claim 1 wherein the equipment-side coolant circuit is a closed loop coolant circuit.

3. The heat exchange apparatus of claim 1 wherein the second coolant in-flow and out-flow valves in fluid communication with the coolant supply source are comprised in an open loop coolant circuit.

4. The heat exchange apparatus of claim 1 wherein the first coolant in-flow and out-flow direction is opposite to the second coolant in-flow and out-flow direction respectively

5. The heat exchange apparatus of claim 1 wherein, the heat exchange apparatus is a rack mounted module operatively coupled to a corresponding rack mounted electronic server module wherein the first coolant in-flow and out-flow compartment is comprised in a rack mounted closed loop coolant distribution unit and the second coolant in-flow and out-flow compartment is comprised in an open loop coolant distribution unit.

6. The heat exchange apparatus of claim 1 further comprising a control system comprising:
a sensor arrangement configured to measure at least one of a volume of liquid coolant in each of the coolant in-flow and out-flow compartments, and a rate of change of liquid coolant volume in each of the compartments, wherein measurements measured by the sensor arrangement are monitored by the control system to detect faults; and based on detected faults the control system is configured to generate an alarm signal responsive to a rate of change in the volume of liquid coolant in a coolant reservoir being above a predefined threshold value.

7. The heat exchange apparatus of claim 6 wherein based on the detected faults derived from the change of liquid coolant volume, the control system causes a negative pressure to be created in the equipment-side coolant circuit, and the first and second coolant in-flow and out-flow compartments to eliminate any spillage of liquid coolant.

8. The heat exchange apparatus of claim 6 wherein the first coolant in-flow and out-flow compartment contains at least one of a fluid and water.

9. The heat exchange apparatus of claim 6 wherein the second coolant in-flow and out-flow compartment contains water pumped from a proximal naturally available source.

10. In a heat exchange apparatus, a method comprising:
initiating fluid communication between an equipment-side coolant circuit with a first coolant compartment via a corresponding first coolant in-flow and out-flow valve;
initiating fluid communication between a coolant supply source and a second coolant compartment operatively coupled to the first coolant compartment via a corresponding second coolant in-flow and out-flow valve;
wherein the first coolant compartment receives hot coolant via the first coolant in-flow valve from a heat transfer element comprised in the equipment side coolant circuit coupled to a heat generating source and in fluid communication with the first coolant in-flow valve, and the first coolant out-flow vale returns the coolant to the heat transfer element comprised in the equipment side coolant circuit; and
wherein the second coolant compartment receives cold coolant from the coolant supply source via the second coolant in-flow valve and returns the received cold coolant to the coolant supply source via the second coolant out-flow valve.

11. The method of claim 10 wherein the initiating the fluid communication between the equipment-side coolant circuit with the first coolant compartment comprises initiating a closed loop circuit fluid communication.

12. The method of claim 10 wherein the initiating the fluid communication between the coolant supply source and the second coolant compartment comprises initiating an open loop circuit fluid communication.

13. The method of claim 10 wherein the fluid communication between the equipment-side coolant circuit and the first coolant compartment is in an opposite direction to the fluid communication between the coolant supply source and the second coolant compartment.

14. The method of claim 10 further comprising operatively coupling the heat exchange to a rack mounted electronic server module such that the first coolant compartment is comprised in a rack mounted closed loop coolant distribution unit and the second coolant compartment operatively coupled to the first coolant compartment is comprised in an open loop coolant distribution unit.

15. The method of claim 10 further comprising:
in a control system, measuring at least one of a volume of liquid coolant in each of the coolant compartments, and a rate of change of liquid coolant volume in each of the compartments, wherein measurements measured by the sensor arrangement are monitored by the control system to detect faults; and
based on detected faults, generating an alarm signal responsive to a rate of change in the volume of liquid coolant in a coolant reservoir being above a predefined threshold value.

16. The method of claim 15 wherein based on the detected faults derived from the change of liquid coolant volume, creating a negative pressure in the equipment-side coolant circuit, and the first and second coolant compartments to eliminate any spillage of liquid coolant.

17. The method of claim 16 wherein the first coolant compartment contains at least one of a fluid and water.

18. The method of claim 16 further comprising pumping water from a proximal naturally occurring source through the second coolant compartment.

19. A cooling apparatus for facilitating cooling of an electronic system, the cooling apparatus comprising:
a liquid-cooled cooling structure comprising a first heat transfer element configured to stack beneath or above the electronic system, the liquid-cooled cooling structure comprising a thermally conductive material and comprising at least one coolant-carrying channel extending there through;
a second heat transfer element coupled to one or more corresponding heat-generating components of the electronic system, and configured to physically contact the liquid-cooled cooling structure, wherein each heat transfer element physically engages the liquid-cooled cooling structure, and wherein each heat transfer element provides a thermal transport path from the one or more heat-generating components of the electronic system to the liquid-cooled cooling structure stacked beneath or above the electronic system; and
a third heat transfer element operatively coupled to the second heat transfer element, comprising a thermally conductive material and at least one coolant carrying channel extending there through.
